(19) United States
(12) Patent Application Publication
(10) Pub. No.: US 2023/0034270 A1
(43) Pub. Date: Feb. 2, 2023

(54) Optical Fiber Illumination by a Set of Light Emitters

(71) Applicant: Apple Inc., Cupertino, CA (US)

(72) Inventors: Brian S. Medower, San Jose, CA (US); Eamon H. O'Connor, Emeryville, CA (US); Keith Lyon, San Jose, CA (US); Marc A. Drader, Waterloo (CA); Salman Karbasi, San Jose, CA (US); Shifa Xu, Palo Alto, CA (US); Yazan Z. Alnahhas, Stanford, CA (US)

(21) Appl. No.: 17/865,169

(22) Filed: Jul. 14, 2022

Related U.S. Application Data
(60) Provisional application No. 63/226,347, filed on Jul. 28, 2021.

(51) Int. Cl. H01S 5/183; H01S 5/42; H01S 5/00; F21V 8/00

(52) U.S. Cl. CPC H01S 5/18302; H01S 5/423; H01S 5/0085; G02B 6/0008

(57) ABSTRACT

An electronic device includes a substrate, a set of light emitters on the substrate and arranged in a plurality of axisymmetric light emitter groups, a set of lenses including a different lens disposed over each axisymmetric light emitter group of the plurality of axisymmetric light emitter groups, and a set of optical fibers. At least one optical fiber in the set of optical fibers has a proximal end, a distal end, and a bend between the proximal end and the distal end. The proximal end is positioned to receive light, through a respective lens in the set of lenses, from the light emitters of a respective axisymmetric light emitter group in the plurality of axisymmetric light emitter groups.

### CROSS-REFERENCE TO RELATED APPLICATION

This application is a nonprovisional and claims the benefit under 35 U.S.C. 119(e) of U.S. Provisional Patent Application No. 63/226,347, filed Jul. 28, 2021, the contents of which are incorporated herein by reference as if fully disclosed herein.

### FIELD

The described embodiments generally relate to illumination projectors. More particularly, the described embodiments enable the geometric integration of illumination projectors into devices having small or thin form factors and/or devices having limited or disjoint space or area to house an illumination projector.

### BACKGROUND

Many of today's devices include or require an illumination projector. For example, it may be useful to provide a device having a camera with a flash, floodlight, or spotlight—all of which are forms of visible illumination projectors. It may be useful to provide a device having a biometric acquisition or authentication device with one or more of a non-visible (e.g., infrared (IR)) floodlight, spot/dot illumination projector, and so on. It may be useful to provide a device having a depth sensor with an illumination projector that emits dots, lines, or a flood of non-visible illumination. It may be useful to provide a device capable of sensing various health or fitness-related parameters an illumination projector that can emit visible and/or non-visible light into a user's tissue. It may also be useful to incorporate a flashlight or other visible light navigation feature into a device.

### SUMMARY

Embodiments of the systems, devices, methods, and apparatus described in the present disclosure pertain to illumination projectors having sets of light emitters, sets of optical fibers, and various types of interfaces between the sets of light emitters and sets of optical fibers (e.g., different sizes, arrangements, and/or groupings of light emitters; different sizes, arrangements, and/or groupings of optical fibers; different correspondences of light emitters to optical fibers; and/or different kinds of gaps or gap fillers between the light emitters and the optical fibers).

In a first aspect, an electronic device is described. The electronic device may include a substrate, a set of light emitters on the substrate and arranged in a plurality of axisymmetric light emitter groups, a set of lenses including a different lens disposed over each axisymmetric light emitter group of the plurality of axisymmetric light emitter groups, and a set of optical fibers. One or more of the optical fibers in the set of optical fibers may each have a proximal end, a distal end, and a bend between the proximal end and the distal end. The proximal end may be positioned to receive light, through a respective lens in the set of lenses, from the light emitters of a respective axisymmetric light emitter group in the plurality of axisymmetric light emitter groups.

In a second aspect, an illumination projector is described. The illumination projector may include a substrate, an array of light emitters on the substrate, and a set of optical fibers. The set of optical fibers may include an array of proximal ends positioned to receive light from at least some of the light emitters in the array of light emitters, a set of distal ends, and a bend between the proximal end and the distal end of at least one optical fiber in the set of optical fibers.

In addition to the exemplary aspects and embodiments described above, further aspects and embodiments will become apparent by reference to the drawings and by study of the following description.

### BRIEF DESCRIPTION OF THE DRAWINGS

The disclosure will be readily understood by the following detailed description in conjunction with the accompanying drawings, wherein like reference numerals designate like structural elements, and in which:

FIGS. 1A and 1B show an example of a device that may include an illumination projector;

FIG. 2 shows an example block diagram of an electronic device;

FIGS. 3A and 3B show example block diagrams of illumination projectors;

FIGS. 4A and 4B show an example arrangement of components of an illumination projector in relation to a camera barrel;

FIGS. 5A-5C show a first example interface between a set of light emitters and a set of optical fibers;

FIG. 5D shows an alternative to the interface shown in FIG. 5C;

FIGS. 6A-6C show a second example interface between a set of light emitters and a set of optical fibers;

FIG. 6D shows an alternative to the interface shown in FIGS. 6A-6C;

FIG. 7 shows a third example interface between a set of light emitters and a set of optical fibers; and

FIG. 8 shows a fourth example interface between a set of light emitters and a set of optical fibers.

The use of cross-hatching or shading in the accompanying figures is generally provided to clarify the boundaries between adjacent elements and also to facilitate legibility of the figures. Accordingly, neither the presence nor the absence of cross-hatching or shading conveys or indicates any preference or requirement for particular materials, material properties, element proportions, element dimensions, commonalities of similarly illustrated elements, or any other characteristic, attribute, or property for any element illustrated in the accompanying figures.

Additionally, it should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

### DETAILED DESCRIPTION

Reference will now be made in detail to representative embodiments illustrated in the accompanying drawings. It should be understood that the following description is not intended to limit the embodiments to one preferred embodiment. To the contrary, it is intended to cover alternatives, modifications, and equivalents as can be included within the spirit and scope of the described embodiments as defined by the appended claims.

Some devices (e.g., mobile phones, tablet or portable computers, wearable devices such as electronic watches, and so on) may have small or thin form factors, or may have limited or disjoint space or area to house an illumination projector (e.g., because of the need to house other components). Embodiments of the systems, devices, methods, and apparatus described in the present disclosure enable the layout of an illumination projector to be geometrically engineered for a particular device, including devices having small or thin form factors or limited or disjoint space or area to house an illumination projector. In some embodiments, a set of light emitters may be positioned where convenient (e.g., where convenient given the layout of the device), but the position of the set of light emitters may not allow the set of light emitters to emit light in a desired direction. For example, a set of light emitters may be positioned such that the beam axes of the set of light emitters intersect an opaque structure of the device (e.g., a sidewall or cover of the device). To provide illumination in a desired direction, the proximal ends of a set of optical fibers may be positioned to intersect the beam axes of the set of light emitters and receive light from the set of light emitters. Some or all of the optical fibers may be bent to redirect the light that is received into their proximal ends. The distal ends of the optical fibers may be positioned and oriented to emit the illumination provided by the set of light emitters in a desired direction.

In addition to redirecting the light emitted by the set of light emitters, the optical fibers may alter the footprint of the emitted light. For example, the set of light emitters may be arranged in an m×n array, where m is a number of rows in the array, and n is a number of columns in the array. The distal ends of the optical fibers, however, may be positioned in one or more rings around a structure such as a camera barrel or speaker.

The above and other aspects of the described illumination projectors minimize geometric module integration constraints for illumination projectors.

Various types of interfaces between a set of light emitters and a set of optical fibers (e.g., different sizes, arrangements, and/or groupings of light emitters; different sizes, arrangements, and/or groupings of optical fibers; different correspondences of light emitters to optical fibers; and/or different kinds of gaps or gap fillers between the light emitters and the optical fibers) may improve the efficiency of light propagation from the set of light emitters to the distal ends of the set of optical fibers. In some embodiments, one or more lenses (e.g., microlenses) may be used to direct light emitted by a set of light emitters into a set of optical fibers.

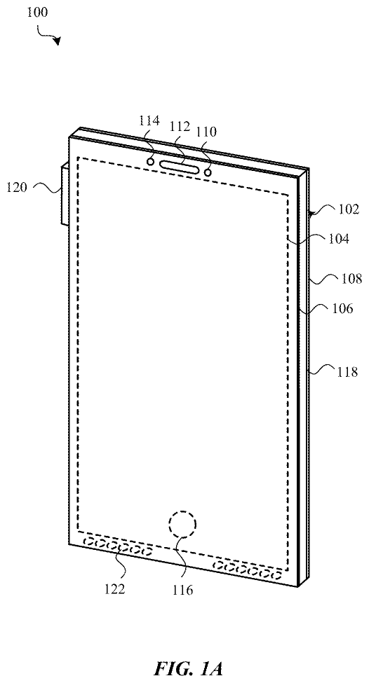

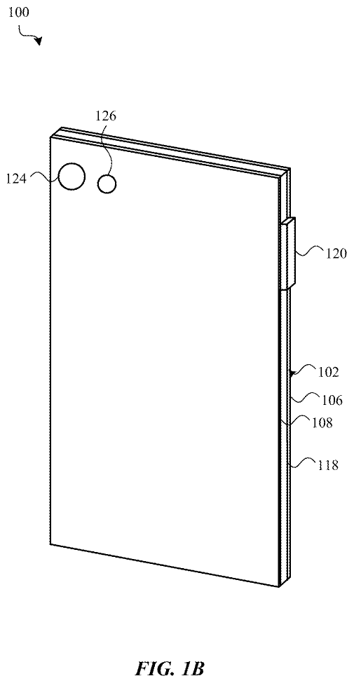

These and other systems, devices, methods, and apparatus are described with reference to FIGS. 1A-8. However, those skilled in the art will readily appreciate that the detailed description given herein with respect to these figures is for explanatory purposes only and should not be construed as limiting.

Directional terminology, such as “top”, “bottom”, “upper”, “lower”, “front”, “back”, “over”, “under”, “above”, “below”, “left”, “right”, etc. is used with reference to the orientation of some of the components in some of the figures described below. Because components in various embodiments can be positioned in a number of different orientations, directional terminology is used for purposes of illustration and is not always limiting. Directional terminology is intended to be construed broadly, and therefore should not be interpreted to preclude components being oriented in different ways. Also, as used herein, the phrase “at least one of” preceding a series of items, with the term “and” or “or” to separate any of the items, modifies the list as a whole, rather than each member of the list. The phrase “at least one of” does not require selection of at least one of each item listed; rather, the phrase allows a meaning that includes at a minimum one of any of the items, and/or one of any combination of the items, and/or one of each of the items. By way of example, the phrases “at least one of A, B, and C” or “at least one of A, B, or C” each refer to only A, only B, or only C; any combination of A, B, and C; and/or one or more of each of A, B, and C. Similarly, it may be appreciated that an order of elements presented for a conjunctive or disjunctive list provided herein should not be construed as limiting the disclosure to only that order provided.

FIGS. 1A and 1B show an example of a device 100 that may include an illumination projector. The device's dimensions and form factor, including the ratio of the length of its long sides to the length of its short sides, suggest that the device 100 is a mobile phone (e.g., a smartphone). However, the device's dimensions and form factor are arbitrarily chosen, and the device 100 could alternatively be any portable electronic device including, for example a mobile phone, tablet computer, portable computer, portable music player, wearable device (e.g., an electronic watch, health monitoring device, or fitness tracking device), augmented reality (AR) device, virtual reality (VR) device, mixed reality (MR) device, gaming device, portable terminal, digital single-lens reflex (DSLR) camera, video camera, vehicle navigation system, robot navigation system, or other portable or mobile device. The device 100 could also be a device that is semi-permanently located (or installed) at a single location. FIG. 1A shows a front isometric view of the device 100, and FIG. 1B shows a back isometric view of the device 100. The device 100 may include a housing 102 that at least partially surrounds a display 104. The housing 102 may include or support a front cover 106 that defines a front surface of the device 100, and/or a back cover 108 that defines a back surface of the device 100 (with the back surface opposite the front surface). More generically, the device 100 may include one or more “covers.” The front cover 106 may be positioned over the display 104, and may provide a window through which the display 104 may be viewed. In some embodiments, the display 104 may be attached to (or abut) the housing 102 and/or the front cover 106. In alternative embodiments of the device 100, the display 104 may not be included and/or the housing 102 may have an alternative configuration.

The display 104 may include one or more light-emitting elements, and in some cases may be a light-emitting diode (LED) display, an organic LED (OLED) display, a liquid crystal display (LCD), an electroluminescent (EL) display, or another type of display. In some embodiments, the display 104 may include, or be associated with, one or more touch and/or force sensors that are configured to detect a touch and/or a force applied to a surface of the front cover 106.

The various components of the housing 102 may be formed from the same or different materials. For example, a sidewall 118 of the housing 102 may be formed using one or more metals (e.g., stainless steel), polymers (e.g., plastics), ceramics, or composites (e.g., carbon fiber). In some cases, the sidewall 118 may be a multi-segment sidewall including a set of antennas. The antennas may form structural components of the sidewall 118. The antennas may be structurally coupled (to one another or to other components) and electrically isolated (from each other or from other components) by one or more non-conductive segments of the sidewall 118. The front cover 106 may be formed, for example, using one or more of glass, a crystal (e.g., sapphire), or a transparent polymer (e.g., plastic) that enables a user to view the display 104 through the front cover 106. In some cases, a portion of the front cover 106 (e.g., a perimeter portion of the front cover 106) may be coated with an opaque ink to obscure components included within the housing 102. The back cover 108 may be formed using the same material(s) that are used to form the sidewall 118 or the front cover 106. In some cases, the back cover 108 may be part of a monolithic element that also forms the sidewall 118 (or in cases where the sidewall 118 is a multi-segment sidewall, those portions of the sidewall 118 that are conductive or non-conductive). In still other embodiments, all of the exterior components of the housing 102 may be formed from a transparent material, and components within the device 100 may or may not be obscured by an opaque ink or opaque structure within the housing 102.

The front cover 106 may be mounted to the sidewall 118 to cover an opening defined by the sidewall 118 (i.e., an opening into an interior volume, in which various electronic components of the device 100, including the display 104, may be positioned). The front cover 106 may be mounted to the sidewall 118 using fasteners, adhesives, seals, gaskets, or other components.

A display stack or device stack (hereafter referred to as a “stack”) including the display 104 may be attached (or abutted) to an interior surface of the front cover 106 and extend into the interior volume of the device 100. In some cases, the stack may include a touch sensor (e.g., a grid of capacitive, resistive, strain-based, ultrasonic, or other type of touch sensing elements), or other layers of optical, mechanical, electrical, or other types of components. In some cases, the touch sensor (or part of a touch sensor system) may be configured to detect a touch applied to an outer surface of the front cover 106 (e.g., to a display surface of the device 100).

In some cases, a force sensor (or part of a force sensor system) may be positioned within the interior volume above, below, and/or to the side of the display 104 (and in some cases within the device stack). The force sensor (or force sensor system) may be triggered in response to the touch sensor detecting one or more touches on the front cover 106 (or a location or locations of one or more touches on the front cover 106), and may determine an amount of force associated with each touch, or an amount of force associated with a collection of touches as a whole. In some embodiments, the force sensor (or force sensor system) may be used to determine a location of a touch, or a location of a touch in combination with an amount of force of the touch. In these latter embodiments, the device 100 may not include a separate touch sensor.

As shown primarily in FIG. 1A, the device 100 may include various other components. For example, the front of the device 100 may include one or more front-facing cameras 110, speakers 112, microphones, or other components 114 (e.g., audio, imaging, and/or sensing components) that are configured to transmit or receive signals to/from the device 100. In some cases, a front-facing camera 110, alone or in combination with other sensors, may be configured to operate as a bio-authentication or facial recognition sensor. The device 100 may also include various input devices, including a mechanical or virtual button 116, which may be accessible from the front surface (or display surface) of the device 100. In some embodiments, a virtual button 116 may be displayed on the display 104 and, in some cases, a fingerprint sensor may be positioned under the button 116 and configured to image a fingerprint through the display 104. In some embodiments, the fingerprint sensor or another form of imaging device may span a greater portion, or all, of the display area.

The device 100 may also include buttons or other input devices positioned along the sidewall 118 and/or on a back surface of the device 100. For example, a volume button or multipurpose button 120 may be positioned along the sidewall 118, and in some cases may extend through an aperture in the sidewall 118. In other embodiments, the button 120 may take the form of a designated and possibly raised portion of the sidewall 118, but the button 120 may not extend through an aperture in the sidewall 118. The sidewall 118 may include one or more ports 122 that allow air, but not liquids, to flow into and out of the device 100. In some embodiments, one or more sensors may be positioned in or near the port(s) 122. For example, an ambient pressure sensor, ambient temperature sensor, internal/external differential pressure sensor, gas sensor, particulate matter concentration sensor, or air quality sensor may be positioned in or near a port 122.

In some embodiments, the back surface of the device 100 may include a rear-facing camera 124 that includes one or more image sensors (see FIG. 1B). A flash or light source 126 may also be positioned on the back of the device 100 (e.g., near the rear-facing camera). In some cases, the back surface of the device 100 may include multiple rear-facing cameras.

Although not illustrated in FIGS. 1A and 1B, the device 100 may also include an illumination projector. The illumination projector may provide flood, spot, patterned, sustained, and/or pulsed illumination, depending on its configuration. The illumination projector may also provide visible illumination (e.g., illumination of one or more colors) and/or non-visible illumination (e.g., infrared (IR) or ultraviolet (UV) illumination). As described with reference to other figures herein, the illumination projector may provide a set of light emitters (e.g., a set of vertical cavity surface-emitting lasers (VCSELs), edge-emitting lasers (EELs), horizontal cavity surface-emitting lasers (HCSELs), quantum dot lasers (QDLs), light-emitting diodes (LEDs), and so on) that emit light into a set of optical fibers. One or more or all of the optical fibers may be bent, thereby enabling the set of light emitters to be positioned where convenient, and using the optical fibers to change the beam axis (i.e., optical beam axis) of one or more of the light emitters. In some cases, the beam of light emitted by a light emitter may illuminate a proximal end of more than one optical fiber. In some cases, the beams of light emitted by more than one light emitter may illuminate a proximal end of an optical fiber. The distal ends of the optical fibers may be disposed uniformly, where convenient, or where desired around a camera barrel of the front-facing camera 110, the rear-facing camera 124, a speaker 112, a microphone, a button 120, a port 122, the display 104, and/or other components 114. Light exiting the distal ends of the optical fibers may pass through the front or back cover 106, 108 or through the sidewall 118 or, in some cases, the optical fibers may extend through the front or back cover 106, 108 or sidewall 118. In some embodiments, all of the light emitted by a set of light emitters may exit from a common feature (e.g., from around a camera barrel of the front or rear-facing camera 110, 124). In some embodiments, the light emitted by a set of light emitters (e.g., a co-located set of light emitters) may exit from different features (e.g., from around the camera barrels of both the front and rear-facing cameras 110, 124; or from around the front-facing camera 110 and the speaker 112).

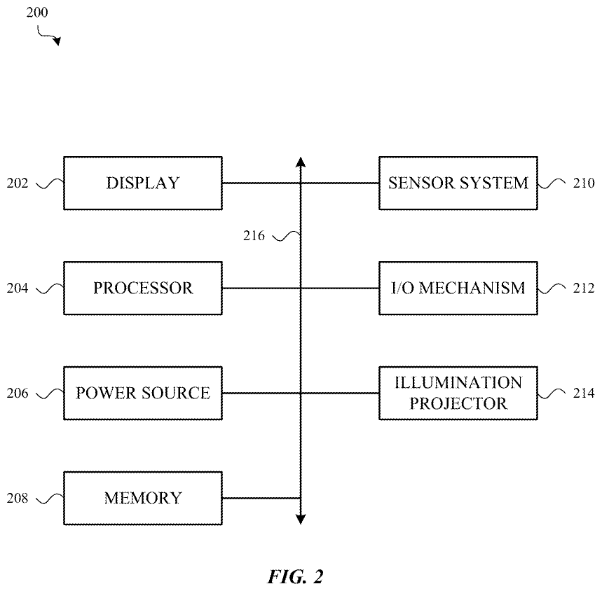

FIG. 2 shows an example block diagram of an electronic device 200, which in some cases may be the electronic device described with reference to FIGS. 1A and 1B, or another type of electronic device including one or more of the illumination projectors described herein. The electronic device 200 may include an electronic display 202 (e.g., a light-emitting display), a processor 204, a power source 206, a memory 208 or storage device, a sensor system 210, an input/output (I/O) mechanism 212 (e.g., an input/output device, input/output port, or haptic input/output interface), and/or an illumination projector 214. The processor 204 may control some or all of the operations of the electronic device 200. The processor 204 may communicate, either directly or indirectly, with some or all of the other components of the electronic device 200. For example, a system bus, other bus(es), or other communication mechanism 216 can provide communication between the electronic display 202, the processor 204, the power source 206, the memory 208, the sensor system 210, the I/O mechanism 212, and the illumination projector 214.

The processor 204 may be implemented as any electronic device capable of processing, receiving, or transmitting data or instructions, whether such data or instructions is in the form of software or firmware or otherwise encoded. For example, the processor 204 may include a microprocessor, a central processing unit (CPU), an application-specific integrated circuit (ASIC), a digital signal processor (DSP), a controller, or a combination of such devices. As described herein, the term “processor” is meant to encompass a single processor or processing unit, multiple processors, multiple processing units, or other suitably configured computing element or elements. In some cases, the processor 204 may provide part or all of the processing system or processor described herein.

It should be noted that the components of the electronic device 200 can be controlled by multiple processors. For example, select components of the electronic device 200 (e.g., the sensor system 210) may be controlled by a first processor and other components of the electronic device 200 (e.g., the electronic display 202) may be controlled by a second processor, where the first and second processors may or may not be in communication with each other.

The power source 206 can be implemented with any device capable of providing energy to the electronic device 200. For example, the power source 206 may include one or more batteries or rechargeable batteries. Additionally or alternatively, the power source 206 may include a power connector or power cord that connects the electronic device 200 to another power source, such as a wall outlet.

The memory 208 may store electronic data that can be used by the electronic device 200. For example, the memory 208 may store electrical data or content such as, for example, audio and video files, documents and applications, device settings and user preferences, timing signals, control signals, instructions, and/or data structures or databases. The memory 208 may include any type of memory. By way of example only, the memory 208 may include random access memory, read-only memory, Flash memory, removable memory, other types of storage elements, or combinations of such memory types.

The electronic device 200 may also include one or more sensor systems 210 positioned almost anywhere on the electronic device 200. The sensor system(s) 210 may be configured to sense one or more types of parameters, such as but not limited to, vibration; light; touch; force; heat; movement; relative motion; biometric data (e.g., biological parameters) of a user; air quality; proximity; position; connectedness; surface quality; and so on. By way of example, the sensor system(s) 210 may include a heat sensor, a position sensor, a light or optical sensor, a self-mixing interferometry (SMI) sensor, an image sensor (e.g., one or more of the image sensors or cameras described herein), an accelerometer, a pressure transducer, a gyroscope, a magnetometer, a health monitoring sensor, an air quality sensor, and so on. Additionally, the one or more sensor systems 210 may utilize any suitable sensing technology, including, but not limited to, interferometric, magnetic, capacitive, ultrasonic, resistive, optical, acoustic, piezoelectric, or thermal technologies.

The I/O mechanism 212 may transmit or receive data from a user or another electronic device. The I/O mechanism 212 may include the electronic display 202, a touch sensing input surface, a crown, one or more buttons (e.g., a graphical user interface “home” button), one or more microphones or speakers, one or more ports such as a microphone port, and/or a keyboard. Additionally or alternatively, the I/O mechanism 212 may transmit electronic signals via a communications interface, such as a wireless, wired, and/or optical communications interface. Examples of wireless and wired communications interfaces include, but are not limited to, cellular and Wi-Fi communications interfaces.

The illumination projector 214 may be configured as described with reference to FIGS. 1A and 1B and elsewhere herein, and in some cases may be integrated or used in conjunction with one or more of the sensor system(s) 210. For example, the illumination projector 214 may illuminate an object or scene, and light that reflects or scatters from the object or scene may be sensed by a light or optical sensor, an SMI sensor, or an image sensor (e.g., one or more of the image sensors or cameras described herein). In some embodiments, an illumination projector 214 may be part of a sensor system 210.

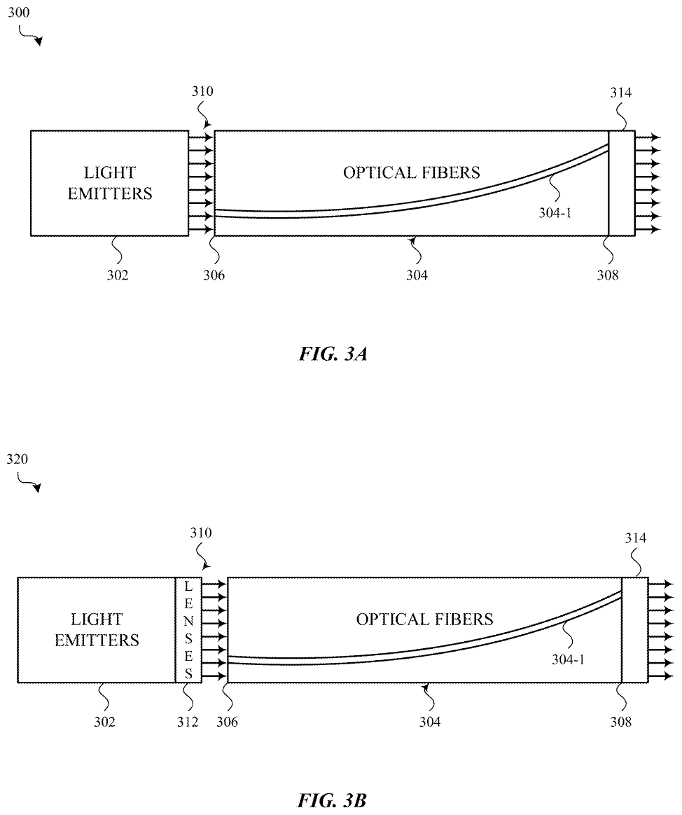

FIG. 3A shows a first example block diagram of an illumination projector 300. In some cases, the illumination projector 300 may be one of the illumination projectors described with reference to FIG. 1A, 1B, or 2.

The illumination projector 300 may include a set of light emitters 302 and a set of optical fibers 304. For purposes of this description, a light emitter 302 may be any structure that emits visible light (e.g., red, green, blue, or other wavelengths or colors of visible light) or non-visible light (e.g., near infrared (IR), IR, ultraviolet, or other wavelengths of non-visible light). In various embodiments, the set of light emitters 302 may include VCSELs, EELs, HCSELs, QDLs, LEDs, and so on.

The optical fibers 304 may have proximal ends 306 positioned near the set of light emitters 302. The optical fibers 304 may have distal ends 308 from which light received into the set of optical fibers 304 may be emitted. At least one of the optical fibers 304-1 may have one or more bends (i.e., a curvature, or one or more arcuate changes in direction) between its proximal end 306 and its distal end 308. In some embodiments, all of the optical fibers 304 may have one or more bends. Different optical fibers 304 may be bent in the same or different ways (i.e., different optical fibers 304 may have different curvatures and/or bends at different distances from their proximal or distal ends 306, 308). The bends in the optical fibers 304 not only provide a geometric independence between the position of the set of light emitters 302 and the position of the distal ends 308 of the optical fibers 304, but also help scramble the optical modes of the light emitted by the light emitters 302, which scrambling helps diffuse the light that exits the distal ends 308 of the optical fibers 304.

In some embodiments, the set of light emitters 302 may, collectively, emit light into each optical fiber in the set of optical fibers 304. In some embodiments, the set of light emitters 302 may, collectively, emit light into a subset of optical fibers that is fewer than all of the optical fibers in the set of optical fibers 304.

In some embodiments, one or more light emitters in the set of light emitters 302 may each emit light into a single optical fiber 304. In some embodiments, each of one or more light emitters 302 may each emit light into multiple optical fibers 304.

The light emitters 302 and/or optical fibers 304 may in some cases be grouped. For example, subsets of light emitters 302 may be grouped, and/or subsets of optical fibers 304 may be grouped. Each light emitter group may include a subset of light emitters 302 that includes light emitters 302 positioned relatively closer to one another on a substrate, and/or in a predefined pattern that is discernible from the predefined patterns formed by the light emitters 302 of other light emitter groups, and/or in a predefined pattern that defines one or more larger spacings between at least one of the light emitters 302 of the light emitter group and at least one light emitter 302 of another light emitter group. The light emitters 302 of a light emitter group may collectively or individually emit light into one or more multiple optical fibers 304. Each optical fiber group (or optical fiber bundle) may include a subset of optical fibers that includes optical fibers 304 positioned relatively closer to other optical fibers 304 within an optical fiber group and/or optical fibers 304 that are otherwise physically grouped. In some cases, the optical fibers 304 of an optical fiber group may be surrounded by a shared cladding, or may be bonded to one another or encapsulated with one another. Each optical fiber group may receive light from one or more light emitters 302. When both light emitters 302 and optical fibers 304 are grouped, the light emitter groups and optical fiber groups may have a one-to-one, one-to-many, or many-to-one correspondence, and in some cases may not have any correspondence.

The set of optical fibers 304 may be optionally separated from the set of light emitters 302 by a gap 310 (e.g., an air gap) and/or a fill material. When present, the fill material may in some cases be an optically clear adhesive (OCA). In some embodiments, the fill material may include one or more lenses 312 (e.g., a set of microlenses) or other optic elements, as shown in the context of the illumination projector 320 shown in FIG. 3B. In some embodiments, the gap 310 may be filled by an OCA (e.g., an OCA that bridges the distance between the lenses 312 and the optical fibers 304). The lenses 312 or other optic elements may be used to focus, direct, shape, or otherwise direct light into one or more optical fibers in the set of optical fibers 304. A lens 312 or other optic element may be disposed over a distal end of one optical fiber 304, or over the distal ends of multiple optical fibers 304.

The distal ends 308 of the optical fibers 304 may extend to or through a cover 314 or other housing component of a device. The cover 314 (or other housing component) may be formed of glass, plastic, or another material that is optically transparent or translucent to a wavelength of light (or range of light wavelengths) emitted by the set of light emitters 302, and the optical fibers 304 may be positioned and oriented to direct the light that is emitted by the set of light emitters 302 through the cover 314. Or, if the optical fibers 304 extend through the cover 314, the cover 314 may be opaque to the wavelength of light (or range of light wavelengths) emitted by the set of light emitters 302. Optionally, a gap and/or fill material may be provided between the distal ends of the optical fibers 304 and the cover 314. When a fill material is provided between the distal ends 308 of the optical fibers 304 and the cover 314, the fill material may take the form of an optic element, such as a diffuser, lens, or other type of optic element.

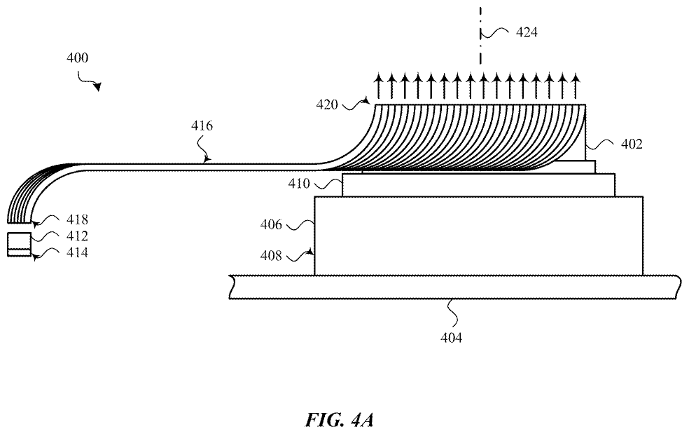

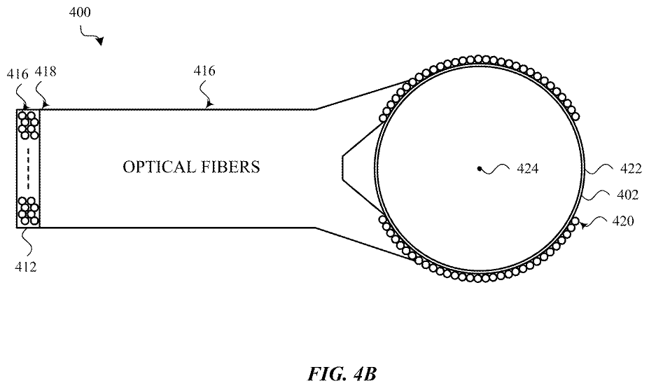

FIGS. 4A and 4B show an example arrangement of components of an illumination projector 400, in relation to a camera barrel 402. FIG. 4A shows an example elevation of the components of the illumination projector in relation to the camera barrel 402, and FIG. 4B shows an example plan view of the components in relation to the camera barrel 402. In some cases, the illumination projector 400 may be one of the illumination projectors described with reference to FIG. 1A, 1B, 2, 3A, or 3B. In some cases, the camera barrel 402 may be a camera barrel of the front-facing camera or rear-facing camera described with reference to FIG. 1A or 1B.

FIG. 4A shows the camera barrel 402 attached to a housing 404 of a device, by means of a camera brace 406 or other structure. In some embodiments, the camera barrel 402 may be part of a camera module 408. In some embodiments, the camera barrel 402 may be attached to a substrate 410, on or to which an image sensor or other camera components are formed or attached. In some embodiments, one or more optic, electrical, or mechanical components may be housed within the camera barrel 402. For example, one or more electrically or mechanically controllable lenses may be housed within the camera barrel 402. Light may enter the camera barrel 402 and be focused on an image sensor.

The illumination projector 400 may include a substrate 412 on which a set of light emitters 414 is arranged. The substrate 412 may also be attached to the housing 404, and may be laterally offset from the camera barrel 402. The set of light emitters 414 may include VCSELs, EELs, HCSELs, QDLs, LEDs, and so on. A set of optical fibers 416 extends generally between the set of light emitters 414 and the periphery of the camera barrel 402. For example, proximal ends 418 of the optical fibers 416 may be positioned near the light emitters 414 (e.g., as described with reference to FIG. 3A or 3B), and distal ends 420 of the optical fibers 416 may be distributed around the circumference of the camera barrel 402 (e.g., around a rim 422 of the camera barrel 402, in one or more circumferential rings, or randomly, or in optical fiber groups). In some embodiments, the distal ends 420 may be positioned and oriented to emit light parallel to an optical axis 424 of the camera barrel 402. In some embodiments, the distal ends 420 may be positioned and/or oriented to emit light in other directions.

As shown, each of the optical fibers 416 may have a bend between its proximal end and its distal end. Different optical fibers 416 may be bent in the same or different ways as other optical fibers 416. Depending on where the substrate 412 and light emitters 414 are positioned, some optical fibers may not need to be bent. By bending the optical fibers 416, the substrate 412 and light emitters 414 may be offset from the camera barrel 402 and/or a camera module, and may be positioned in an available space that does not interfere with the area or space requirements of the camera barrel 402, a camera module, and/or other components.

In some embodiments, all of the optical fibers 416 may have the same length, so that photons entering the proximal ends 418 of the optical fibers 416 at the same time exit the distal ends 420 of the optical fibers 416 at the same time or about the same time. In other embodiments, different optical fibers 416 may have different lengths.

Although FIGS. 4A and 4B show how the components of an illumination projector 400 may be arranged with respect to a camera barrel 402, the ability to bend the optical fibers 416 of the illumination projector 400 enables the illumination projector 400 to be integrated with other structures as well, with the light emitters 414 being positioned to emit light in directions that are not the directions that light needs to be emitted. The bends in the optical fibers 416 can then redirect the emission direction of the light as needed for a particular application.

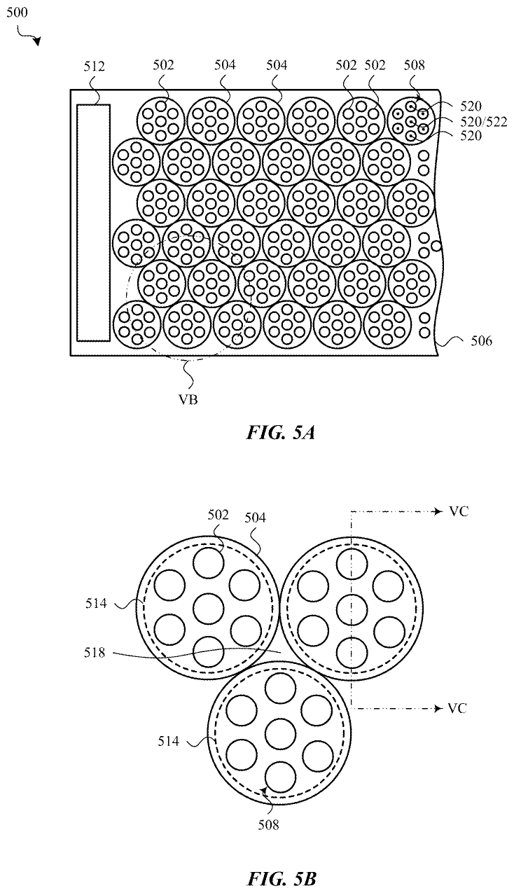

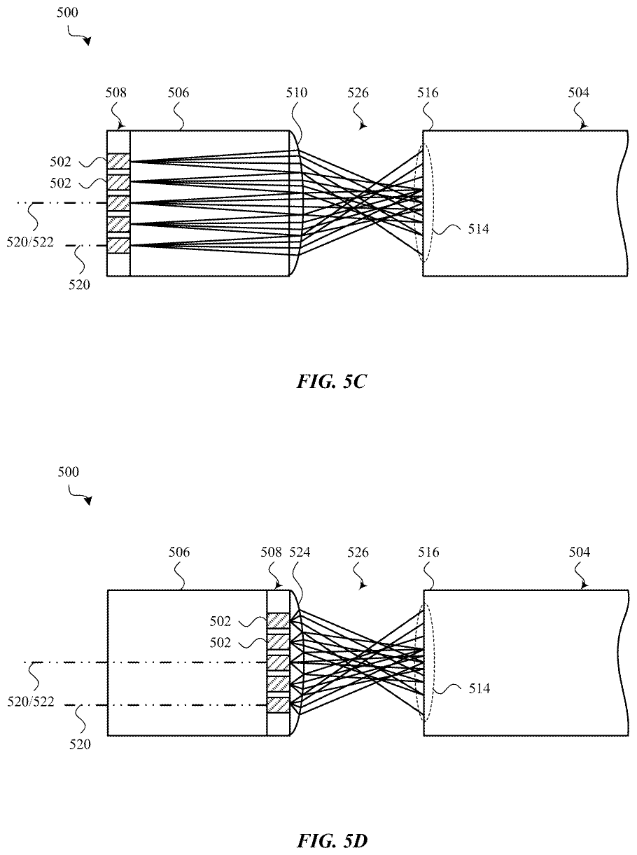

FIGS. 5A-5C show a first example interface 500 between a set of light emitters 502 and a set of optical fibers 504. In some cases, the set of light emitters 502 and set of optical fibers 504 may be part of the illumination projector described with reference to FIG. 1A, 1B, 2, 3A, 3B, 4A, or 4B.

FIG. 5A shows a plan view of a substrate 506 on which the set of light emitters 502 is arranged. The set of light emitters 502 may include VCSELs, EELs, HCSELs, QDLs, LEDs, and so on. The set of light emitters 502 is arranged on the substrate 506 in a plurality of light emitter groups 508. By way of example, the light emitter groups 508 are axisymmetric light emitter groups (i.e., groups in which a subset of light emitters is arranged symmetrically about a central optical axis, such that the light emitter group is symmetric about the central optical axis along any diameter drawn through the central optical axis). In other examples, the light emitter groups 508 need not be axisymmetric.

Each axisymmetric light emitter group 508 may include a subset of light emitters 502 having respective beam axes 520 disposed around an axis 522 of the axisymmetric light emitter group 508, and a light emitter 502 having a beam axis 520 aligned with the axis 522 of the axisymmetric light emitter group 508 (see, e.g., FIG. 5C). In alternative embodiments, the axisymmetric light emitter group 508 may not include the light emitter 502 that has its beam axis 520 aligned with the axis 522 of the axisymmetric light emitter group 508. Although FIG. 5A shows an axisymmetric light emitter group 508 having one ring of light emitters disposed around the axis 522, an axisymmetric light emitter group 508 may alternatively have light emitters 502 disposed along multiple rings around, or at different distances from, the axis 522 of the axisymmetric light emitter group 508. In some embodiments, different light emitter groups 508 may have different numbers or arrangements of light emitters 502.

In some embodiments, the set of light emitters 502 may be formed in, and share, a set of epitaxial layers on the substrate 506. In other embodiments, the set of light emitters 502 may be attached to the substrate 506 individually or in groups.

In some embodiments, an electrical interface 512 may be formed on the substrate 506 and/or in a set of epitaxial layers on the substrate 506. The electrical interface 512 may provide a means for operating the set of light emitters 502, and may include a plurality of conductive traces, electrical contacts, and/or electrical components.

FIG. 5B shows an exploded plan view of some of the light emitters 502 and light emitter groups 508 shown in FIG. 5A (i.e., an exploded plan view of region VB). As shown, the proximal ends of a set of optical fibers 504 may be aligned to receive light from the light emitter groups 508. For example, a proximal end of a particular optical fiber 504 may receive light from the light emitters 502 of a respective light emitter group 508. A halo around each light emitter group 508 identifies the approximate footprint 514 of a beam of light, produced by a light emitter group 508, as it is received into the proximal end of an optical fiber 504. The footprint 514 may have a diameter (or a varied diameter) that is less than or equal to a diameter of an optical fiber 504, so that all of the light emitted by the light emitters 502 of a light emitter group 508 impinges on the proximal end of an optical fiber 504. When the footprints 514 are contained within the boundary defined by a proximal end of an optical fiber 504, light emitted by the light emitters 502 is not lost in the interstitial areas 518 between adjacent optical fibers 504.

The diameter of each light emitter in the set of light emitters 502 may be less than a diameter of each optical fiber in the set of optical fibers 504. In some embodiments, the diameters of the light emitters 502 or the optical fibers 504 may be smaller or larger, or the diameters of the light emitters 502 or the optical fibers 504 may vary.

The proximal ends of the optical fibers in the set of optical fibers 504 may be packed in an array of proximal ends of the optical fibers 504 (i.e., each optical fiber in the set of optical fibers has a proximal end abutted to the proximal ends of adjacent optical fibers in the set of optical fibers 504). Alternatively, some or all of the proximal ends of the optical fibers in the set of optical fibers 504 may be separated from adjacent optical fibers by a gap (e.g., an air gap) and/or fill material. Regardless of whether the optical fibers are packed or spaced apart from one another, the optical fibers may in some cases include cladding (e.g., optical shielding along the length thereof, which may prevent light that enters the proximal end of an optical fiber from escaping the optical fiber, and which may prevent light that does not enter the proximal end of the optical fiber from entering the wall of the optical fiber).

FIG. 5C shows an axial cross-section of one of the light emitter groups 508 and optical fibers 504 shown in FIG. 5B, in combination with the substrate 506 and a lens 510. The cross-section is taken along the cut line VC-VC in FIG. 5B.

A set of lenses 510 (e.g., microlenses) may be disposed over the set of light emitters 502 shown in FIGS. 5A, 5B, and 5C. In some cases, a different lens in the set of lenses 510 may be disposed over each light emitter group 508 (i.e., there may be a one-to-one correspondence of lenses 510 to light emitter groups 508), as shown in FIG. 5C. When a lens is positioned over a light emitter group 508, and in general, eliminating the light emitter 502 that has its beam axis 520 aligned with the axis 522 of the axisymmetric light emitter group 508 and/or moving the beam axes of the light emitters 502 in a light emitter group 508 more toward the periphery of an optical fiber 504, tends to increase the numerical aperture (NA) of the light emitter group 508.

In some cases, the set of light emitters 502 may be constructed as a set of backside illumination (BSI) emitters that emit (or have a primary emission) through the substrate 506. In these cases, the set of lenses 510 may be formed in (e.g., etched into) the substrate 506, as shown in FIG. 5C. In some cases, the substrate 506 may be a Gallium Arsenide (GaAs) substrate. In other cases, the set of light emitters 502 may be constructed as a set of frontside illumination (FSI) emitters that emit (or have a primary emission) away from the substrate 506. In some FSI or BSI cases, a set of lenses 524 may be positioned over, and optionally attached to, a set of epitaxial layers or the substrate 506, as shown in FIG. 5D.

Light emitted by the light emitters 502 of a light emitter group 508 may be focused by a lens 510 such that the beams of light emitted by the light emitters 502 are received at a proximal end 516 of an optical fiber 504 with a footprint 514 having a diameter (or a varied diameter) that is less than the diameter of the optical fiber 504.

The proximal end 516 of the optical fiber 504 may be separated from the lens 510 by a gap 526 (e.g., an air gap) and/or fill material. The fill material may include an OCA or other material, as described with reference to FIGS. 3A and 3B for example.

An advantage of the interface 500 is that use of the set of lenses 510, to steer the beam axes of the light emitters 502 in a light emitter group 508 into a footprint 514 positioned on the proximal end 516 of a singular optical fiber 504, limits the loss of optical power as a result of light entering the interstitial areas 518 between optical fibers 504. An additional advantage is that the far field irradiance distribution may be tailored by appropriate selection of the emitter mode structure for a light emitter 502 and lens (e.g., lens 510 or 524) design, thereby enhancing the performance of, or eliminating the need for, a diffuser or beam shaping element at the distal end of an optical fiber 504.

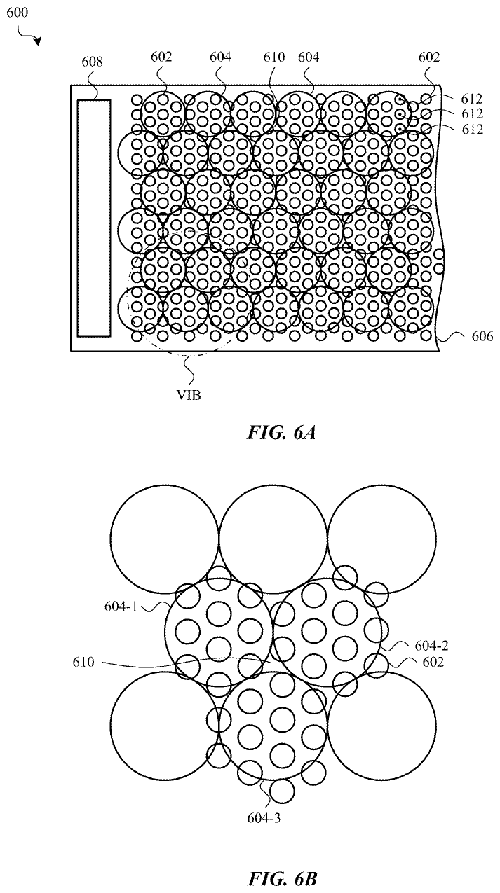

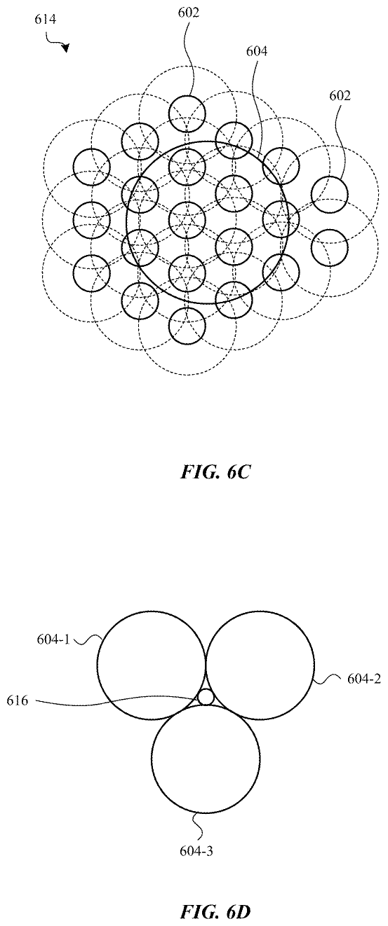

FIGS. 6A-6C show a second example interface 600 between a set of light emitters 602 and a set of optical fibers 604. In some cases, the set of light emitters 602 and set of optical fibers 604 may be part of the illumination projector described with reference to FIG. 1A, 1B, 2, 3A, 3B, 4A, or 4B.

FIG. 6A shows a plan view of a substrate 606 on which the set of light emitters 602 is arranged. The set of light emitters 602 may include VCSELs, EELs, HCSELs, QDLs, LEDs, and so on. In contrast to what is shown in FIG. 5A, the set of light emitters 602 shown in FIG. 6A is arranged on the substrate 606 as a contiguous two-dimensional (2D) array of light emitters (i.e., the light emitters 602 are not arranged in a plurality of light emitter groups).

In some embodiments, the set of light emitters 602 may be formed in, and share, a set of epitaxial layers on the substrate 606. In some embodiments, the set of light emitters 602 may be attached to the substrate 606 individually or in groups. The substrate 606 and light emitters 602 may be used in a BSI or FSI configuration.

In some embodiments, an electrical interface 608 may be formed on the substrate 606 and/or in a set of epitaxial layers on the substrate 606, as described, for example, with reference to FIG. 5A. The electrical interface 608 may provide a means for operating the set of light emitters 602, and may include a plurality of conductive traces, electrical contacts, and/or electrical components.

FIG. 6A also shows, in relation to the array of light emitters 602, the placement of an array of proximal ends of a set of optical fibers 604. As shown, the beam axes of different subsets of light emitters 602 may intersect the proximal ends of different optical fibers 604. In some cases, different numbers of beam axes may intersect the proximal ends of different optical fibers 604. The beam axes of different subsets of light emitters 602 may also intersect different proximal ends in different positional relationships or patterns. For example, the beam axes of eight light emitters 602 intersect the proximal end of an optical fiber 604-1, and the beam axes of ten light emitters 602 intersect the proximal end of an optical fiber 604-2. The beam axes of some light emitters 602 may not intersect the proximal end of any optical fiber 604, and some or all of the light emitted by these light emitters 602 may enter voids between the optical fibers 604, not enter one or more of the optical fibers 604, and not propagate toward the distal ends of the optical fibers 604.

The diameter of each light emitter in the array of light emitters 602 may be less than a diameter of each optical fiber in the set of optical fibers 604. In some embodiments, the diameters of the light emitters 602 or the optical fibers 604 may be smaller or larger, or the diameters of the light emitters 602 or the optical fibers 604 may vary.

The proximal ends of the optical fibers in the set of optical fibers 604 may be packed in an array of proximal ends of the optical fibers 604 (i.e., each optical fiber in the set of optical fibers has a proximal end abutted to the proximal ends of adjacent optical fibers in the set of optical fibers 604). Alternatively, some or all of the proximal ends of the optical fibers in the set of optical fibers 604 may be separated from adjacent optical fibers by a gap (e.g., an air gap) and/or fill material. Regardless of whether the optical fibers are packed or spaced apart from one another, the optical fibers may in some cases include cladding (e.g., optical shielding along the length thereof, which may prevent light that enters the proximal end of an optical fiber from escaping the optical fiber, and which may prevent light that does not enter the proximal end of the optical fiber from entering the wall of the optical fiber).

FIG. 6B shows an exploded plan view of some of the light emitters 602 and some of the optical fibers 604 shown in FIG. 6A (i.e., an exploded plan view of region VIB). For illustration purposes only, some of the light emitters 602 that are positioned and oriented to emit light into or around the optical fibers 604 are not shown. Instead, only the light emitters 602 that have beam axes aligned with, or disposed between, a set of three adjacent optical fibers 604-1, 604-2, 604-3 is shown.

When the set of optical fibers 604 is separated from the array of light emitters 602 by a gap (e.g., an air gap) and/or fill material (e.g., an OCA), the beam of light emitted by each light emitter 602 may diverge and not be focused on the proximal end of a singular optical fiber 604. The beams of light emitted by the light emitters 602 may also be caused to diverge, by positioning appropriate lenses or other optic elements between the array of light emitters 602 and the set of optical fibers 604. In these embodiments, the beams of light emitted by at least some of the light emitters 602 may impinge on the proximal ends of more than one optical fiber 604, or some or all of the beams of light may propagate into interstitial spaces 610 between optical fibers 604. More particularly, a proximal end of an optical fiber 604 may intersect a first set of beam axes 612 of a first subset of light emitters in the array of light emitters 602, but the proximal end of the optical fiber 604 may receive light from both 1) the first subset of light emitters, and 2) a second subset of light emitters in the array of light emitters 602. The second subset of light emitters may have a second set of beam axes that does not intersect the proximal end of the optical fiber 604, but diverging portions of the beams of light emitted by the light emitters in the second subset may spill over the proximal end of the optical fiber 604 and, in some cases, enter the optical fiber 604.

FIG. 6C shows a further exploded plan view of a singular optical fiber 604 in relation to a subset of light emitters in the array of light emitters 602. More specifically, FIG. 6C illustrates how, because of the divergence of the beams of light emitted by the subset of light emitters, all of the light emitters positioned within a zone 614 may contribute to the total amount of light that impinges on a proximal end of the optical fiber 604.

Optionally, a set of lenses (e.g., microlenses) may be positioned over the array of light emitters 602. The lenses may have diameters that are approximately the same size as the diameters of the optical fibers 604, and may have optical axes aligned with the axes of the optical fibers 604 (e.g., a single lens may have an optical axis that is aligned with the axis of a respective optical fiber 604).

In some embodiments of the interface 600, one or more optical fibers 616 having diameters smaller than those of the optical fibers 604 may be used to partially fill the interstitial spaces 610 between the optical fibers 604 and limit the optical power loss between the optical fibers 604, as shown in FIG. 6D.

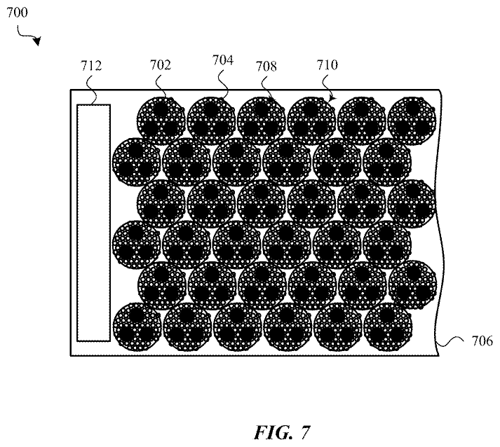

FIG. 7 shows a plan view of a third example interface 700 between a set of light emitters 702 and a set of optical fibers 704. In some cases, the set of light emitters 702 and set of optical fibers 704 may be part of the illumination projector described with reference to FIG. 1A, 1B, 2, 3A, 3B, 4A, or 4B.

More particularly, FIG. 7 shows a substrate 706 on which the set of light emitters 702 is arranged. The set of light emitters 702 may include VCSELs, EELs, HCSELs, QDLs, LEDs, and so on. The set of light emitters 702 is arranged on the substrate 706 in a plurality of light emitter groups 708. By way of example, each light emitter group 708 is shown to include three light emitters forming a triangular pattern. In other embodiments, each light emitter group 708 may include more, fewer, or the same number of light emitters, arranged in any number of patterns.

In some embodiments, the set of light emitters 702 may be formed in, and share, a set of epitaxial layers on the substrate 706. In other embodiments, the set of light emitters 702 may be attached to the substrate 706 individually or in groups.

In some embodiments, an electrical interface 712 may be formed on the substrate 706 and/or in a set of epitaxial layers on the substrate 706. The electrical interface 712 may provide a means for operating the set of light emitters 702, and may include a plurality of conductive traces, electrical contacts, and/or electrical components.

Also shown in FIG. 7 is an array of optical fiber groups 710. Each optical fiber group 710 may include a set of optical fibers 704.

In contrast to what is shown in FIGS. 5A and 6A, the diameter of each light emitter in the array of light emitters 702 may be greater than a diameter of each optical fiber in an optical fiber group 710, but less than the diameter (or varying diameter) of an optical fiber group 710. In some embodiments, the diameters of the light emitters 702, optical fibers 704, or optical fiber groups 710 may be smaller or larger, or the diameters of the light emitters 702, optical fibers 704, or optical fiber groups 710 may vary.

By way of example, the proximal ends of the optical fibers 704 in each optical fiber group 710 are shown packed in an array of proximal ends of the optical fibers 704 (i.e., each optical fiber 704 in an optical fiber group 710 has a proximal end abutted to the proximal ends of adjacent optical fibers in the optical fiber group 710). Similarly, the proximal ends of the optical fiber groups 710 are shown packed in an array of proximal ends of optical fiber groups 710 (i.e., each optical fiber group 710 has a proximal end abutted to the proximal ends of adjacent optical fiber groups 710). In alternative embodiments, some or all of the proximal ends of the optical fiber groups 710 may be separated from the proximal ends of adjacent optical fiber groups 710 by a gap (e.g., an air gap) and/or fill material.

The optical fibers 704 may in some cases include cladding (e.g., optical shielding along the length thereof, which may prevent light that enters the proximal end of an optical fiber from escaping the optical fiber, and which may prevent light that does not enter the proximal end of the optical fiber from entering the wall of the optical fiber).

A beam of light emitted by a light emitter may have a beam axis that is or is not aligned with a particular optical fiber, but the beam of light may illuminate the proximal ends of multiple optical fibers 704 in an optical fiber group 710. The beams of light (i.e., the set of beams) emitted by the light emitters 702 of a light emitter group 708 may provide illumination to all or only some of the optical fibers 704 in an optical fiber group 710. Some of the light emitted by the light emitters 702 may be lost in the fill material or gaps (e.g., interstitial areas) between adjacent optical fibers 704 and/or in the fill material or gaps (e.g., interstitial areas) between adjacent optical fiber groups 710.

The proximal ends of the optical fibers 704 may be separated from the light emitters 702 by a gap (e.g., an air gap) and/or fill material (e.g., an OCA), as described with reference to FIGS. 3A and 3B for example.

In some embodiments, a diffuser may be positioned to receive light exiting the distal ends of the optical fibers 704, or the distal ends of the optical fibers 704 may be shaped such that the distal ends of the optical fibers function as diffusers. The diffuser may be formed of glass or plastic, for example.

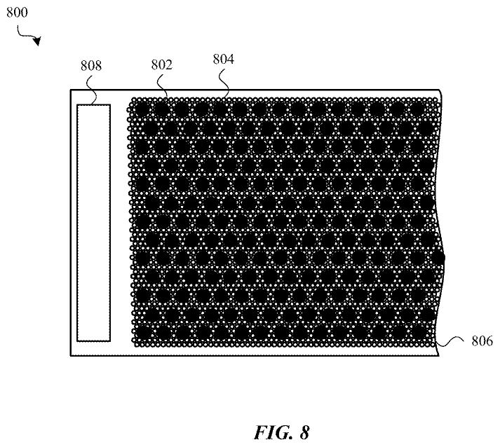

FIG. 8 shows a fourth example interface 800 between a set of light emitters 802 and a set of optical fibers 804. In some cases, the set of light emitters 802 and set of optical fibers 804 may be part of the illumination projector described with reference to FIG. 1A, 1B, 2, 3A, 3B, 4A, or 4B.

More particularly, FIG. 8 shows a substrate 806 on which the set of light emitters 802 is arranged. The set of light emitters 802 may include VCSELs, EELs, HCSELs, QDLs, LEDs, and so on. The set of light emitters 802 may be arranged on the substrate 806 in a uniformly spaced array of light emitters 802. In alternative embodiments, the light emitters 802 may be spaced farther or closer apart, or may be positioned adjacent one another.

In some embodiments, the set of light emitters 802 may be formed in, and share, a set of epitaxial layers on the substrate 806. In other embodiments, the set of light emitters 802 may be attached to the substrate 806 individually or in groups.

In some embodiments, an electrical interface 808 may be formed on the substrate 806 and/or in a set of epitaxial layers on the substrate 806. The electrical interface 808 may provide a means for operating the set of light emitters 802, and may include a plurality of conductive traces, electrical contacts, and/or electrical components.

Also shown in FIG. 8 is a set of optical fibers 804. The set of optical fibers 804 may be arranged on the substrate 806 in a closely packed array of optical fibers 804. In alternative embodiments, the optical fibers 804 may be spaced apart from one another.

Similarly to what is shown in FIG. 7, the diameter of each light emitter in the set of light emitters 802 may be greater than a diameter of each optical fiber in the set of optical fibers 804. In some embodiments, the diameters of the light emitters 802 or optical fibers 804 may be smaller or larger, or the diameters of the light emitters 802 or optical fibers 804 may vary.

The optical fibers 804 may in some cases include cladding (e.g., optical shielding along the length thereof, which may prevent light that enters the proximal end of an optical fiber from escaping the optical fiber, and which may prevent light that does not enter the proximal end of the optical fiber from entering the wall of the optical fiber).

A beam of light emitted by a light emitter 802 may have a beam axis that is or is not aligned with a particular optical fiber 804, but the beam of light may illuminate the proximal ends of multiple optical fibers 804. The beams of light emitted by the light emitters 802 may provide illumination to all or only some of the optical fibers 804. Some of the light emitted by the light emitters 802 may be lost in the fill material or gaps (e.g., interstitial areas) between adjacent optical fibers 804.

To ensure a uniform output at the distal ends of the optical fibers 804, each light emitter 802 (or the set of light emitters 802) may need to be aligned with the set of optical fibers 804, so that each light emitter 802 provides the same illumination pattern on the same number and pattern of optical fibers 804.

The proximal ends of the optical fibers 804 may be separated from the light emitters 802 by a gap (e.g., an air gap) and/or fill material (e.g., an OCA), as described with reference to FIGS. 3A and 3B for example.

Although the foregoing description indicates that a set of light emitters may include VCSELs, EELs, HCSELs, QDLs, LEDs, and so on, VCSELs may be preferable in that they can often be manufactured with a higher density and can sometimes have a better-controlled numerical aperture (NA).

The foregoing description, for purposes of explanation, uses specific nomenclature to provide a thorough understanding of the described embodiments. However, it will be apparent to one skilled in the art, after reading this description, that the specific details are not required in order to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art, after reading this description, that many modifications and variations are possible in view of the above teachings.

What is claimed is:

1. An electronic device, comprising:
a substrate;
a set of light emitters on the substrate and arranged in a plurality of axisymmetric light emitter groups;
a set of lenses including a different lens disposed over each axisymmetric light emitter group of the plurality of axisymmetric light emitter groups; and
a set of optical fibers including at least one optical fiber having,
a proximal end positioned to receive light, through a respective lens in the set of lenses, from the light emitters of a respective axisymmetric light emitter group in the plurality of axisymmetric light emitter groups;
a distal end; and
a bend between the proximal end and the distal end.

2. The electronic device of claim 1, wherein the set of light emitters shares a set of epitaxial layers on the substrate.

3. The electronic device of claim 1, wherein each optical fiber in the set of optical fibers has a respective bend between a respective proximal end and a respective distal end.

4. The electronic device of claim 3, wherein the respective bends of at least two optical fibers in the set of optical fibers have different curvatures.

5. The electronic device of claim 1, further comprising:
a housing including,
a sidewall; and
a cover attached to the sidewall;
a display positioned within the housing and viewable through the cover; and
a camera barrel attached to the housing; wherein,
the substrate is attached to the housing and laterally offset from the camera barrel;
the at least one optical fiber includes multiple optical fibers; and
the distal end of each optical fiber in the multiple optical fibers is positioned around the camera barrel.

6. The electronic device of claim 5, wherein the multiple optical fibers are positioned and oriented to direct light emitted by the set of light emitters through the cover.

7. The electronic device of claim 5, wherein:
the housing defines a back surface opposite the cover; and
the multiple optical fibers are positioned and oriented to direct light emitted by the set of light emitters through the back surface.

8. The electronic device of claim 1, wherein an axisymmetric light emitter group comprises a subset of light emitters having respective beam axes disposed around an axis of the axisymmetric light emitter group.

9. The electronic device of claim 8, wherein the axisymmetric light emitter group comprises a light emitter having a beam axis aligned with the axis of the axisymmetric light emitter group.

10. The electronic device of claim 1, wherein the set of lenses is formed in the substrate.

11. The electronic device of claim 1, wherein each optical fiber in the at least one optical fiber has a proximal end separated from a respective lens in the set of lenses by an air gap.

12. An illumination projector, comprising:
a substrate;
an array of light emitters on the substrate; and
a set of optical fibers having,
an array of proximal ends positioned to receive light from at least some light emitters in the array of light emitters;
a set of distal ends; and
a bend between the proximal end and the distal end of at least one optical fiber in the set of optical fibers.

13. The illumination projector of claim 12, wherein each light emitter in the array of light emitters has a diameter that is less than a diameter of each optical fiber in the set of optical fibers.

14. The illumination projector of claim 13, wherein:
an optical fiber in the set of optical fibers has a proximal end intersecting a first set of beam axes of a first subset of light emitters in the array of light emitters; and
the proximal end of the optical fiber receives light from,
the first subset of light emitters; and
a second subset of light emitters in the array of light emitters, the second subset of light emitters having a second set of beam axes that does not intersect the proximal end.

15. The illumination projector of claim 13, wherein:
a first set of beam axes of a first subset of light emitters in the array of light emitters intersects proximal ends of the set of optical fibers; and
a second set of beam axes of a second subset of light emitters in the array of light emitters does not intersect the proximal ends of the set of optical fibers.

16. The illumination projector of claim 13, wherein an optical fiber in the set of optical fibers has a proximal end separated from the array of light emitters by an air gap.

17. The illumination projector of claim 13, wherein each optical fiber in the set of optical fibers has a proximal end abutted to the proximal ends of adjacent optical fibers in the set of optical fibers.

18. The illumination projector of claim 12, wherein each light emitter in the array of light emitters has a diameter that is greater than a diameter of each optical fiber in the set of optical fibers.

19. The illumination projector of claim 18, further comprising a diffuser positioned to receive light exiting the set of distal ends.

20. The illumination projector of claim 18, wherein:
light emitters of the array of light emitters are arranged in a plurality of light emitter groups;
optical fibers of the set of optical fibers are arranged in a plurality of optical fiber groups; and
beam axes of the light emitters of a light emitter group are positioned to intersect proximal ends of at least some of the optical fibers in a respective optical fiber group.
